(19) United States
(12) Patent Application Publication
(10) Pub. No.: US 2015/0275360 A1
(43) Pub. Date: Oct. 1, 2015

(54) Vacuum Processing Apparatus

(71) Applicant: TOKYO ELECTRON LIMITED, Tokyo (JP)

(72) Inventors: Kazuhide HASEBE, Nirasaki City (JP); Akinobu KAKIMOTO, Nirasaki City (JP); Akira SHIMIZU, Nirasaki City (JP)

(21) Appl. No.: 14/666,609

(22) Filed: Mar. 24, 2015

(30) Foreign Application Priority Data
Mar. 25, 2014 (JP) 2014062007

(51) Int. Cl. C23C 16/458; C23C 16/44; C23C 16/455

(52) U.S. Cl. CPC C23C 16/4588; C23C 16/45544; C23C 16/45557; C23C 16/4412

(57) ABSTRACT

Provided is a vacuum processing apparatus, which includes: a rotatable table installed in a vacuum vessel and configured to horizontally rotate around its center axis; a drive mechanism configured to rotate the rotatable table; a plurality of substrate holding units circumferentially arranged on the rotatable table and configured to obliquely hold a plurality of substrates with a front surface of each of the substrates oriented in a rotation direction of the rotatable table; a heating unit configured to heat the substrates held by the substrate holding units; a processing gas supply unit configured to supply a processing gas onto the substrates held by the substrate holding units; and a vacuum exhaust mechanism configured to vacuum-exhaust the interior of the vacuum vessel.

### CROSS-REFERENCE TO RELATED APPLICATION

This application claims the benefit of Japanese Patent Application No. 2014-062007, filed on Mar. 25, 2014, in the Japan Patent Office, the disclosure of which is incorporated herein in its entirety by reference.

### TECHNICAL FIELD

The present disclosure relates to a vacuum processing apparatus which processes a substrate inside a vacuum vessel by supplying a processing gas onto the substrate.

### BACKGROUND

A film forming apparatus has been used as a vacuum processing apparatus for forming a thin film of silicon oxide (SiO₂) on a substrate such as a semiconductor wafer (hereinafter referred to as a “wafer”) using, for example, ALD (Atomic Layer Deposition). Such a film forming apparatus includes a horizontal rotatable table installed inside a processing vessel whose interior is under a vacuum atmosphere. A plurality of concave portions on which wafers are horizontally loaded is formed in the rotatable table in its circumferential direction. In addition, a plurality of gas nozzles is arranged to face the rotatable table.

Processing gas nozzles for supplying a processing gas to form a processing atmosphere and separating gas nozzles for supplying a separating gas to separate processing atmospheres on the rotatable table are alternately arranged. When the wafers are processed, while rotating the rotatable table, the processing gas and the separating gas are supplied from the respective gas nozzles toward the rotatable table and are exhausted through exhaust ports formed in the processing vessel.

However, with the above configuration, the processing gas discharged from the processing gas nozzle collides with a front surface of the wafer so that a flow of the processing gas is blocked in the front surface. The processing gas with its flow blocked is flown over the rotatable table to the exhaust port. As such, rotation speeds of the rotatable table in central and peripheral portions of the rotatable table are different from each other. This makes it difficult to uniformly maintain a flow rate and flow velocity of the processing gas in the central and peripheral portions. As a result, a film thickness in the peripheral portion of the rotatable table may be greater than that of the central portion of the rotatable table.

In addition, although the conventional film forming apparatus can load and process a plurality of wafers on the rotatable table at once, there is a demand to process more wafers at once in order to increase productivity of the apparatus.

### SUMMARY

Some embodiments of the present disclosure provide a vacuum processing apparatus which is capable of performing a film forming process in a plane of a substrate with high uniformity, and enhancing throughput of the apparatus by increasing the number of substrates which can be processed at once.

According to one embodiment of the present disclosure, there is provided a vacuum processing apparatus, which includes: a rotatable table installed in a vacuum vessel and configured to horizontally rotate around its center axis; a drive mechanism configured to rotate the rotatable table; a plurality of substrate holding units circumferentially arranged on the rotatable table and configured to obliquely hold a plurality of substrates with a front surface of each of the substrates oriented in a rotation direction of the rotatable table; a heating unit configured to heat the substrates held by the substrate holding units; a processing gas supply unit configured to supply a processing gas onto the substrates held by the substrate holding units; and a vacuum exhaust mechanism configured to vacuum-exhaust the interior of the vacuum vessel.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a longitudinal sectional side view of a film forming apparatus according to a first embodiment of the present disclosure.

FIG. 2 is an exploded perspective view schematically showing an internal configuration of the film forming apparatus shown in FIG. 1.

FIG. 3 is a cross-sectional plan view of the film forming apparatus shown in FIG. 1.

FIG. 4 is a longitudinal sectional side view of wafer holding units installed in the film forming apparatus shown in FIG. 1.

FIG. 5 is an exploded perspective view of a wafer transfer unit and a wafer holding unit.

FIG. 6 is an explanatory view showing flows of gases in a film forming process by the film forming apparatus shown in FIG. 1.

FIG. 7 is an exploded perspective view showing wafers held by wafer holding units in the film forming process.

FIG. 8 is a longitudinal sectional side view of a film forming apparatus according to a second embodiment of the present disclosure.

FIG. 9 is an exploded perspective view schematically showing an internal configuration of the film forming apparatus shown in FIG. 8.

FIG. 10 is a cross-sectional plan view of the film forming apparatus shown in FIG. 8.

FIG. 11 is a longitudinal sectional side view of a processing gas nozzle in which discharge holes are obliquely opened.

FIG. 12 is an exploded perspective view schematically showing an internal configuration of a film forming apparatus according to a third embodiment of the present disclosure.

FIG. 13 is a cross-sectional plan view of the film forming apparatus shown in FIG. 12.

FIG. 14 is a longitudinal sectional side view of the film forming apparatus shown in FIG. 12.

FIG. 15 is a longitudinal sectional side view of a film forming apparatus according to a fourth embodiment of the present disclosure.

FIG. 16 is an exploded perspective view schematically showing an internal configuration of the film forming apparatus shown in FIG. 15.

FIG. 17 is a perspective view of a substrate holding unit of the film forming apparatus shown in FIG. 15.

FIG. 18 is a schematic plan view showing another example of an arrangement of the wafer holding units.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments. In the following, the same reference numerals used in alternate embodiments refer to the same elements, and thus, a description thereof will be omitted to avoid duplication herein.

### First Embodiment

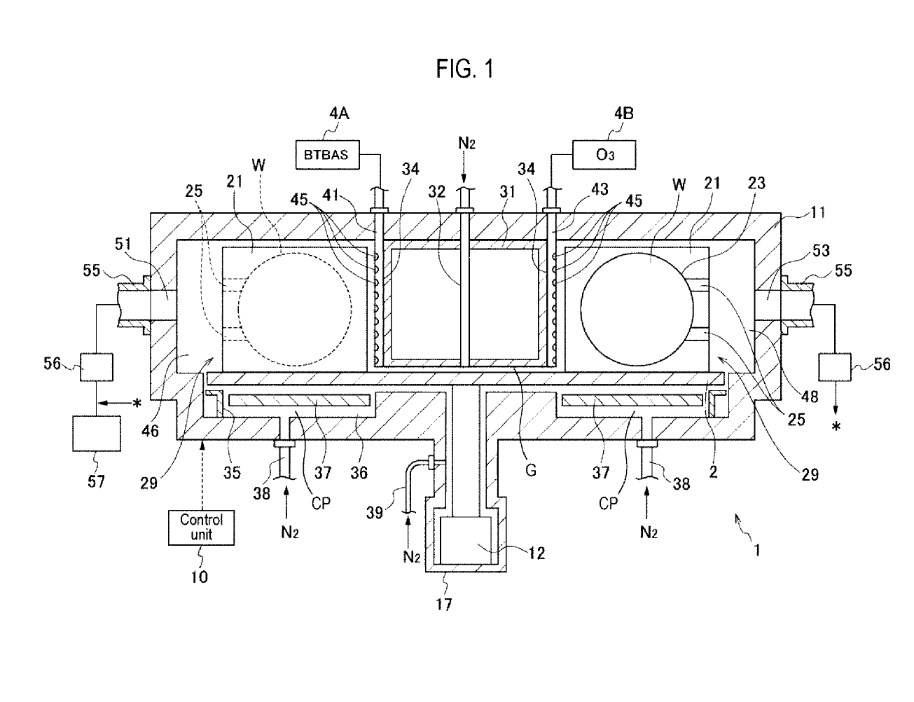

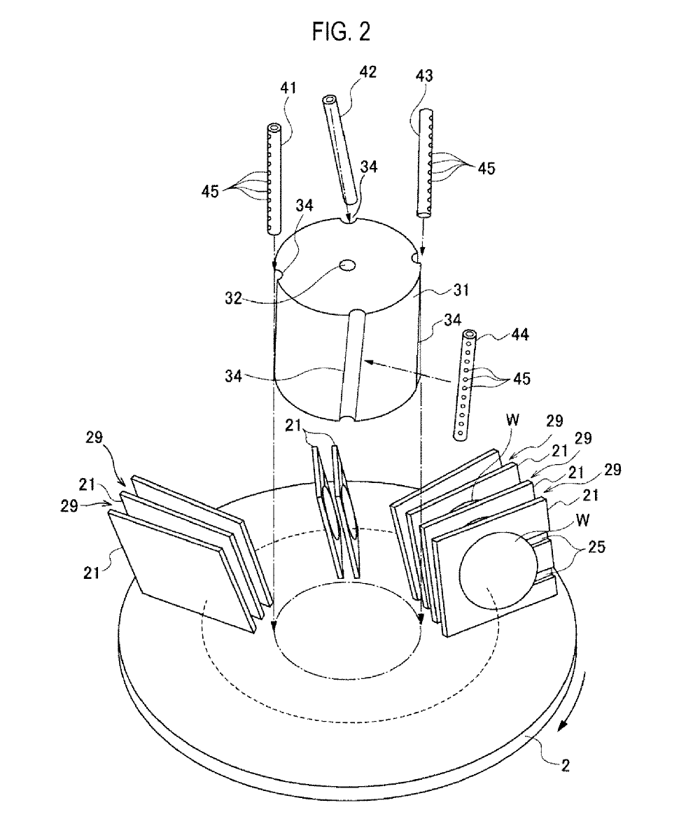

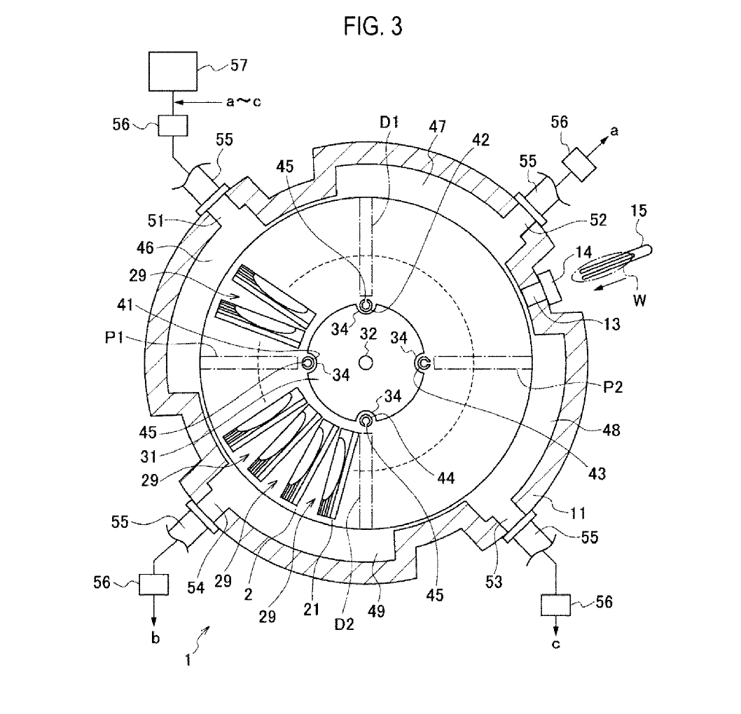

As one embodiment of a vacuum processing apparatus of the present disclosure, a film forming apparatus 1 in which wafers W as substrates are subjected to an ALD process will be described with reference to FIGS. 1 to 3. FIG. 1 is a longitudinal sectional side view of the film forming apparatus 1. FIG. 2 is an exploded perspective view schematically showing an internal configuration of the film forming apparatus 1. FIG. 3 is a cross-sectional plan view of the film forming apparatus 1 when viewed from the top. The film forming apparatus 1 includes a substantially circular flat vacuum vessel (processing vessel) 11 and a horizontal disc-like rotatable table 2 installed within the vacuum vessel 11.

The rotatable table 2, which is made of, e.g., quartz, is connected to a rotary drive mechanism 12. The rotatable table 2 is horizontally rotated around its central axis by the rotary drive mechanism 12. The term “horizontally” is not limited to “strictly horizontally” but may include “somewhat obliquely.” In this embodiment, the rotatable table 2 is rotated clockwise when viewed from the top.

A plurality of (e.g., 50) rectangular plate-like wafer holding units 21, each of which is made of, e.g., quartz, is installed on a front surface of the rotatable table 2. For the sake of simplicity, only some of the wafer holding units 21 are shown in FIGS. 2 and 3. For example, the wafer holding units 21 are arranged at regular intervals along a circumferential direction of the rotatable table 2 while being placed at equal distances from the central axis. Further, the wafer holding units 21 are arranged such that their side surfaces extend along a diameter of the rotatable table 2. In each of FIGS. 1 to 3, a space between two adjacent wafer holding units 21 in the rotation direction of the rotatable table 2 is denoted by reference numeral 29. When the wafer holding units 21 are arranged as described above, each of the spaces 29 is defined to be widened from the inside of the rotatable table 2 toward the outside thereof when viewed from the top.

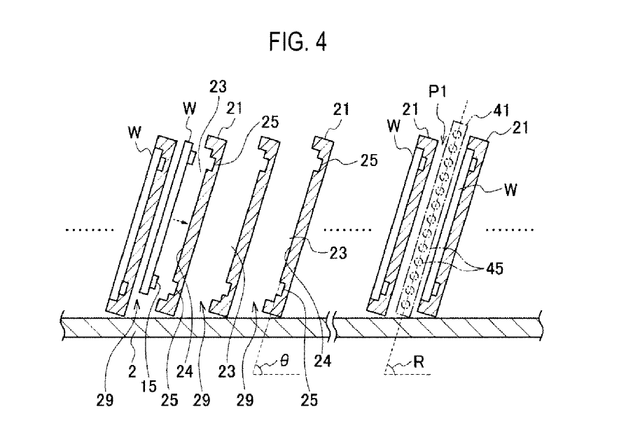

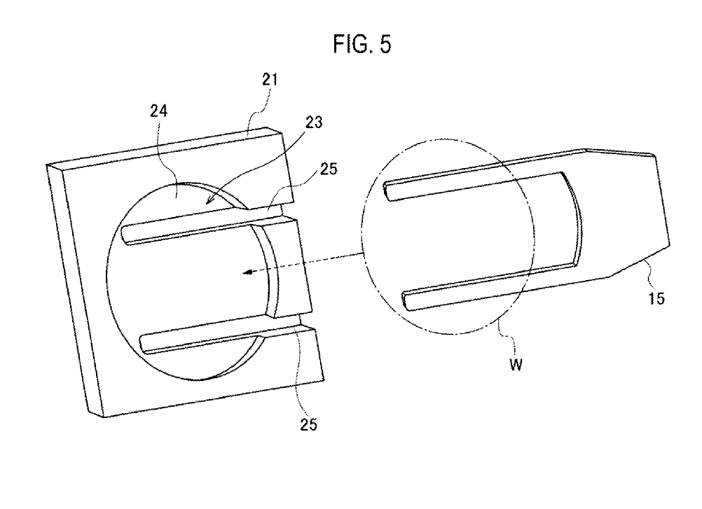

FIG. 4 is a longitudinal sectional side view of each of the wafer holding units 21 arranged in the circumferential direction of the rotatable table 2. As shown in FIGS. 2 and 4, the wafer holding units 21 are obliquely arranged with respect to the rotatable table 2 when viewed from the side. FIG. 5 is a perspective view of the wafer holding unit 21. For the wafer holding unit 21, assuming that a surface located in the rotation direction of the rotatable table 2 is a front surface, a circular concave portion 23 for accommodating the wafer W is formed in the front surface. The wafer W is held by the wafer holding unit 21 while a rear surface of the wafer W is brought into contact with a bottom 24 of the concave portion 23. That is, the wafers W are held by the respective wafer holding units 21 while the front surfaces of the wafers W are positioned in the rotation direction of the rotatable table 2. Further, the wafers W are held in a state where they are inclined with respect to a horizontal plane of the rotatable table 2.

Each of the wafers W held by the wafer holding units 21 is rotated around the central axis of the rotatable table 2 along with the rotation of the rotatable table 2. In the rotation, by virtue of a pressure of a gas supplied into the vacuum vessel 11, the wafers W are subjected to a film forming process in a state where the rear surfaces thereof are brought into close contact with the bottoms 24 of the concave portions 23.

As shown in FIG. 4, an angle θ defined between the horizontal plane of the rotatable table 2 and the bottom 24 of the concave portion 23 shown in FIG. 4 is set to be closer to 90 degrees C. in a range of 0 to 90 degrees C., which makes it possible to install more wafer holding units 21 on the rotatable table 2. This assists in improving throughput of the film forming apparatus 1. However, friction between the rear surface of the wafer W and the bottom 24 of the concave portion 23 becomes smaller as the angle θ becomes closer to 90 degrees C. This may result in a significant risk that the wafers W are detached from the concave portion 23 in the film forming process and a transfer process of the wafer W (which will be described later). Thus, the angle θ may be set to a range of greater than zero to less than 90 degrees C.; in some embodiments, it may set to a range of 30 to 85 degrees C.

On the front surface of the wafer holding unit 21, two linear grooves 25 extending from the peripheral portion of the rotatable table 2 toward the center of the wafer holding unit 21 are formed at a vertical interval. Proximal ends of the grooves 25 are formed on the edge of the wafer holding unit 21 and distal ends of the grooves 25 are formed to overlap with the bottom 24 of the concave portion 23.

Returning to FIG. 3, a transfer port 13 through which the wafer W is transferred is formed in a side wall of the vacuum vessel 11. The transfer port 13 is opened/closed by a gate valve 14. A wafer transfer unit 15 installed out of the film forming apparatus 1 can advance into the vacuum vessel 11 via the transfer port 13. The wafer transfer unit 15 transfers the wafer W to the wafer holding unit 21 positioned at the transfer port 13.

As shown in FIGS. 3 and 5, the wafer transfer unit 15 has a plate-like bifurcated distal end onto which the rear surface of the wafer W is electrostatically adsorbed. The wafer transfer unit 15 is configured to advance to and retreat from the transfer port 13 and vertically move with respect to the bottom 24 of the concave portion 23 of the wafer holding unit 21. The grooves 25 formed in the front surface of the wafer holding unit 21 are formed to accommodate the distal end of the wafer transfer unit 15. The wafer W can be delivered between the concave portion 23 and the wafer transfer unit 15 in cooperation between the advancement/retreatment and the vertical movement of the wafer transfer unit 15.

A columnar median separation part 31 is installed between the central portion of a ceiling plate of the vacuum vessel 11 and the rotatable table 2. The median separation part 31 is located inside a column formed by the arrangement of the wafer holding units 21. The bottom of the median separation part 31 is spaced opposite the central portion of the front surface of the rotatable table 2 by a gap G (see FIG. 1). A central gas nozzle 32 is formed to pass through the central axis of the median separation part 31. A distal end of the central gas nozzle 32 is opened in the bottom of the median separation part 31. A proximal end of the central gas nozzle 32 is drawn out to the outside through the ceiling plate of the vacuum vessel 11 and is connected to a supply source of N₂ gas used as a separating gas (not shown). The N₂ gas supplied from the N₂ gas supply source into the central gas nozzle 32 spreads out radially, when viewed from the top, over the rotatable table 2 through the gap between the median separation part 31 and the rotatable table 2. The N₂ gas can prevent processing gases (which will be described later) from contacting with each other over the central portion of the rotatable table 2.

Four grooves 34 extending obliquely from the top to bottom of the median separation part 31 are formed at intervals along a circumferential direction in a side wall of the median separation part 31. In addition, four rod-like gas nozzles are installed to pass from the outside of the vacuum vessel 11 through the ceiling plate of the vacuum vessel 11. The four gas nozzles are installed to extend obliquely downward through the respective grooves 34. These gas nozzles are arranged in the order of a first processing gas nozzle 41, a separating gas nozzle 42, a second processing gas nozzle 43 and a separating gas nozzle 44 when viewed from the circumferential direction. The first processing gas nozzle 41 constitutes a raw material gas supply unit for supplying a first processing gas (raw material gas) used as a film forming raw material. The second processing gas nozzle 43 constitutes a reaction gas supply unit for supplying a second processing gas (reaction gas) reacting with the film forming raw material.

Each of the gas nozzles 41 to 44 includes a plurality of discharge holes 45 formed at regular intervals along a longitudinal direction. The discharge holes 45 through which gas is discharged in the diameter direction of the rotatable table 2, are formed to face the peripheral portion of the rotatable table 2. This configuration allows the gas to be laterally supplied over the entire surface of the wafer W. The discharge holes 45 of the gas nozzle 41 are shown in FIG. 4. In this embodiment, in order to supply the gas onto the front surface of the wafer W with high uniformity, the gas nozzle 41 is installed in parallel to the front surface of the wafer W held by the wafer holding unit 21. Further, an angle R between a direction in which the discharge holes 45 are arranged and the horizontal plane of rotatable table 2 is equal to the angle θ. Although the gas nozzle 41 has been described as a representative example, the gas nozzles 42 to 44 are also arranged in the same direction as the gas nozzle 41. In some embodiments, the gas nozzles 41 to 44 may be arranged to extend in the vertical direction, i.e., at the angle R of 90 degrees C., as long as they are arranged to form a film on the wafer W.

The first processing gas nozzle 41 discharges a bis-tertiary butylaminosilane (BTBAS) gas as the first processing gas. The second processing gas nozzle 43 discharges an ozone (O₃) gas as the second processing gas. The separating gas nozzles 42 and 44 discharge a nitrogen (N₂) gas as the separating gas. In FIG. 1, each of reference numerals 4A and 4B denotes a BTBAS gas supply sources configured to store the BTBAS gas and supply the same to the processing gas nozzle 41, and an O₃ gas supply source configured to store the O₃ gas and supply the same to the processing gas nozzle 43, based on a control signal inputted thereto (which will be described later). Each of the separating gas nozzles 42 and 44 are connected to a N₂ gas supply source (not shown) in which the N₂ gas is stored, like the gas nozzles 41 and 43.

On the rotatable table 2, first and second processing zones P1 and P2 into which the BTBAS gas and the O₃ gas are respectively introduced from the processing gas nozzles 41 and 43, are indicated by dot-dash lines in FIG. 3. In addition, first and second separating zones D1 and D2 into which the N₂ gases are respectively introduced from the separating gas nozzles 42 and 44, are indicated by dot-dash lines in FIG. 3. Here, the processing zones P1 and P2 and the separating zones D1 and D2 are formed in the opening direction of the discharge holes 45 of the respective gas nozzles 41 to 44. The separating zones D1 and D2 are provided to prevent the BTBAS gas and the O₃ gas from being diffused and reacting with each other in the circumferential direction of the rotatable table 2.

In the side wall of the vacuum vessel 11 are formed four exhaust ports 51 to 54 at intervals in the circumferential direction of the rotatable table 2. When viewed from the circumferential direction, the exhaust port 51 is formed between the first processing zone P1 and the first separating zone D1, and the exhaust port 52 is formed between the first separating zone D1 and the second processing zone P2. In addition, when viewed from the circumferential direction, the exhaust port 53 is formed between the second processing zone P2 and the second separating zone D2, and the exhaust port 54 is formed between the second separating zone D2 and the first processing zone P1.

The exhaust ports 51 and 53 are provided to remove the BTBAS gas and the O₃ gas which are flown from the processing gas nozzles 41 and 43 toward the peripheral portion of the rotatable table 2. More specifically, the exhaust port 51 is used as a BTBAS gas-dedicated exhaust port through which only the BTBAS gas is exhausted, and the exhaust port 53 is used as an O₃ gas-dedicated exhaust port through which only the O₃ gas is exhausted. However, a separating gas and a purge gas (which will be described later) discharged from the median separation part 31 are also exhausted through the exhaust ports 51 and 53.

The exhaust port 52 is provided to exhaust both the separating gas introduced into the first separating zone D1 and the BTBAS gas flown from above the rotatable table 2 toward the peripheral portion of the rotatable table 2 by virtue of the separating gas. The exhaust port 54 is provided to exhaust both the separating gas introduced into the second separating zone D2 and the O₃ gas flown from above the rotatable table 2 toward the peripheral portion of the rotatable table 2 by virtue of the separating gas. The purge gas is also exhausted through the exhaust ports 52 and 54.

One end of each of exhaust pipes 55 is connected to each of the exhaust ports 51 to 54. The other end of each of the exhaust pipes 55 is coupled to an exhaust mechanism 57, which is constituted by a vacuum pump, via an exhaust amount adjusting mechanism 56. An exhaust amount from each of the exhaust ports 51 to 54 is adjusted by the exhaust amount adjusting mechanism 56 installed in the middle of each of the exhaust pipes 55 so that an internal pressure of the vacuum vessel 11 is controlled.

In the side wall of the vacuum vessel 11, an area ranging from the vicinity of the first processing zone P1 to the exhaust port 51 is used as a gas passage 46, and an area ranging from the vicinity of the first separating zone D1 to the exhaust port 52 is used as a gas passage 47. These gas passages 46 and 47 are drawn toward the outside of the vacuum vessel 11 when viewed from the top, respectively. Gases flown to the peripheral portion of the rotatable table 2 are introduced into the exhaust ports 51 and 52 via the gas passages 46 and 47, respectively. In addition, in the side wall of the vacuum vessel 11, an area ranging from the vicinity of the second processing zone P2 to the exhaust port 53 is used as a gas passage 48, and an area ranging from the vicinity of the second separating zone D2 to the exhaust port 54 is used as a gas passage 49. Similarly, these gas passages 48 and 49 are drawn toward the outer side of the vacuum vessel 11 when viewed from the top, respectively. Gases flown to the peripheral portion of the rotatable table 2 are introduced into the exhaust ports 53 and 54 via the gas passages 48 and 49, respectively.

As shown in FIG. 1, a concave portion CP which is formed in a ring shape along the peripheral portion of the rotatable table 2, is formed in the bottom of the vacuum vessel 11. In the concave portion CP, an enclosing member 35 is installed along an outer periphery of the concave portion CP. The inside of the enclosing member 35 constitutes a heater reception area 36 where a heater 37 is installed. The heater 37 used as a heating unit is installed along the circumferential direction of the rotatable table 2. The rotatable table 2 is heated by a radiation heat of the heater 37 so that the wafer W is heated by the heat radiated from the rotatable table 2.

In FIG. 1, reference numeral 38 denotes a first supply pipe through which an N₂ gas used as the purge gas is supplied into the heater reception area 36 during the film forming process. The supply pipe 38 is provided to prevent the heater 37 from deteriorating through contact with the processing gas. In FIG. 1, reference numeral 17 denotes a cover structured to surround the rotary drive mechanism 12, and reference numeral 39 denotes a second supply pipe through which the N₂ gas used as the purge gas is supplied into the cover 17. The N₂ gas supplied from the second supply pipe 39 is flown along the rear surface of the rotatable table 2 toward the peripheral portion of the rotatable table 2. This prevents the processing gas from turning around from the front surface of the rotatable table 2 toward the rear surface thereof.

The film forming apparatus 1 is provided with a control unit 10 implemented with a computer for controlling the entire operation of the apparatus 1. The control unit 10 stores a program for executing the film forming process for the wafer W, which will be described later. The program controls operations of respective components of the film forming apparatus 1 by transmitting control signals to the respective components. Specifically, the program controls various operations such as supply/shutoff of each gas from respective gas supply sources to the respective gas nozzles 41 to 33, the median separation part 31 and so on, the rotation of the rotatable table 2 by the rotary drive mechanism 12, the adjustment of the exhaust amount from the respective exhaust ports 51 to 54 by the exhaust amount adjusting mechanism 56, the supply of power to the heater 37, opening/closing of the gate valve 14, etc. The program is organized with a group of steps to control the operations and execute the film forming process (which will be described later). The program is installed from a storage medium such as a hard disk, a compact disc, a magneto-optical disc, a memory card, a flexible disk or the like into the control unit 10.

Next, the film forming process performed by the film forming apparatus 1 will be described. The interior of the vacuum vessel 11 is exhausted by the exhaust ports 51 to 54 such that the vacuum vessel 11 is maintained at a vacuum atmosphere of a predetermined pressure. The gate valve 14 is opened and the wafer transfer unit 15 holding the wafer W advances into the vacuum vessel 11 through the transfer port 13. Subsequently, as described above, the wafer transfer unit 15 transfers the wafer W to the wafer holding unit 21 which is located at the transfer port 13. Thereafter, once the wafer transfer unit 15 is retracted out of the vacuum vessel 11, the rotatable table 2 rotates and stops the rotation. Then, a subsequent wafer holding unit 21 which does not hold a wafer W is located at the transfer port 13. The wafer transfer unit 15 transfers the wafer W to the subsequent wafer holding unit 21 through the transfer port 13.

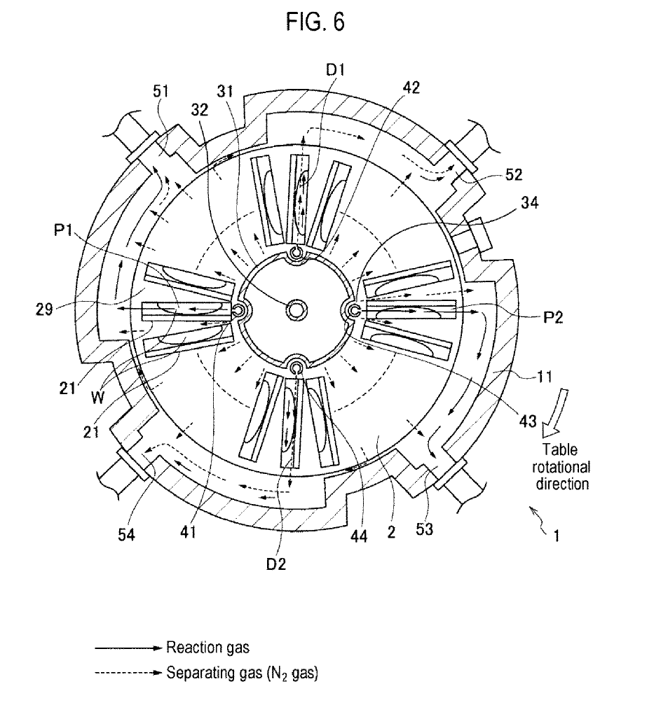

After all the wafers W are loaded into all the wafer holding units 2 by repeating the wafer transfer operation as described above, the gate valve 14 is closed and the wafers W are heated to a predetermined temperature by the heater 37 under a vacuum atmosphere. Subsequently, a predetermined flow rate of the separating gas is supplied from the central gas nozzle 32 of the median separation part 31 and the separating gas nozzles 42 and 44. In addition, in parallel with the supply of the separating gas, the processing gas is supplied from each of the first and second processing gas nozzles 41 and 43 and simultaneously, the rotatable table 2 is rotated at a predetermined rotational speed to start the film forming process. FIG. 6 shows a flow of each gas inside the vacuum vessel 11 in the film forming process. In FIG. 6, a flow of the processing gas is indicated by a solid arrow and a flow of the separating gas is indicated by a dotted arrow.

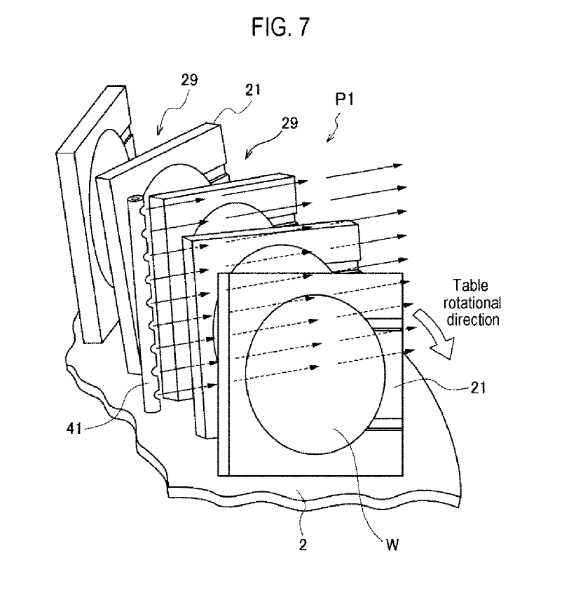

The wafers W alternately pass through the first processing zone P1 defined to face the discharge holes 45 of the first processing gas nozzle 41 and the second processing zone P2 defined to face the discharge holes 45 of the second processing gas nozzle 43. Then, the BTBAS gas is adsorbed on each of the wafers W and subsequently, the O₃ gas is adsorbed on each of the wafers W, thereby oxidizing BTBAS molecules. In this way, one or more molecule layers of silicon oxide are formed. Specifically, as shown in FIG. 7, the BTBAS gas discharged from the first processing gas nozzle 41 passes through the spaces 29 between adjacent wafer holding units 21 and radially flows over the rotatable table 2 toward the peripheral portion of the rotatable table 2.

As compared to the case of supplying the BTBAS gas to be perpendicular to the front surface of the wafer W as described in the BACKGROUND section, the processing gas nozzle 41 of the present disclosure supplies the BTBAS gas toward the spaces 29, thus preventing the BTBAS gas from colliding with and staying on the front surface of the wafer W. Therefore, the BTBAS gas forms a laminar flow flowing along the front surface of the wafer W. This prevents a flow rate and flow velocity of the BTBAS gas from being non-uniform in the plane of the wafer W. That is to say, the BTBAS gas is adsorbed with high uniformity on every area of the plane of the wafer W. For the O₃ gas, since it is supplied in the same way as the BTBAS gas, a high-uniform oxidation reaction occurs in the plane of the wafer W. As a result, a molecule layer is gradually formed with high thickness uniformity in the plane of each of the wafers W.

The BTBAS gas and the O₃ gas, which are discharged from the first and second processing gas nozzles 41 and 43 and are flown to the peripheral portion of the rotatable table 2 without being absorbed on the wafers W, are respectively exhausted through the exhaust ports 51 and 53. Further, the separating gas discharged from the separating gas nozzle 42 to the first separating zone D1 flows on the rotatable table 2 to sweep away the BTBAS gas floating on the rotatable table 2 to the peripheral portion of the rotatable table 2. Thus, both the separating gas and the BTBAS gas are removed through the exhaust port 52. This prevents the BTBAS gas from being introduced into the second processing zone P2. The separating gas discharged from the separating gas nozzle 44 to the second separating zone D2 flows on the rotatable table 2 to sweep away the O₃ gas floating on the rotatable table 2 to the peripheral portion of the rotatable table 2. Thus, both separating gas and the O₃ gas are removed through the exhaust port 54.

With this configuration, the separating gases discharged from the separating gas nozzles 42 and 44 prevent the BTBAS gas and the O₃ gas from being spread in the circumferential direction of the rotatable table 2, thus separating the BTBAS gas and the O₃ gas from each other in the vacuum vessel 11. This prevents particles consisting of reaction products generated by reaction of the BTBAS gas with the O₃ gas, which are floating on the rotatable table 2, from being scattered within the vacuum vessel 11. In addition, an N₂ gas (used as the separating gas) supplied into the median separation part 31 radially flows to the outer side of the rotatable table 2 and is exhausted through each of the exhaust ports 51 to 54. The N₂ gas prevents the BTBAS gas and the O₃ gas on the center of the rotatable table 2 from reacting with each other. In addition, during this film forming process, an N₂ gas used as the purge gas is supplied from the gas supply pipes 38 and 39 to both the heater reception area 36 and the rear surface of the rotatable table 2 such that the processing gases are purged.

As the rotatable table 2 continues to be rotated and each gas continues to be discharged, molecule layers of silicon oxide are sequentially stacked. Upon formation of a silicon oxide film having a predetermined thickness by rotating the rotatable table 2 a predetermined number of times, the supply of respective gases from each of the gas nozzles 41 to 44, each of the gas supply pipes 38 and 39 and the median separation part 31 is stopped. Subsequently, the gate valve 14 is opened, and the wafer transfer unit 15 takes out the wafer W with the silicon oxide film formed thereon from each of the wafer holding units 21 and unloads the same from the vacuum vessel 11, in the reverse order of the aforementioned load operation. Upon completion of the unload operation of all the wafers W from the vacuum vessel 11, the gate valve 14 is closed.

According to this film forming apparatus 1, the plurality of wafer holding units 21 are circumferentially arranged on the rotatable table 2 while obliquely holding the wafers W when viewed from the side. Further, the processing gases supplied from the processing gas nozzles 41 and 43 are controlled to travel from the center of the rotatable table 2 toward the periphery thereof through the spaces 29 formed between the wafer holding units 21. This configuration prevents the flow of the processing gases to the wafers W from being blocked and disturbed, thus allowing the processing gases to flow between the center and the peripheral portion of the rotatable table 2 at a high-uniform flow rate and flow velocity in the planes of the wafers W. Accordingly, it is possible to form a silicon oxide film with high thickness uniformity in the planes of the wafers W. In addition, by installing the wafer holding units 21 as described above, an area per wafer W occupied on the rotatable table 2 can be decreased as compared with a case of placing the wafers W horizontally, thus increasing the number of wafers W placed on the rotatable table 2. Accordingly, it is possible to process more wafers W at once, thereby achieving a higher throughput.

### Second Embodiment

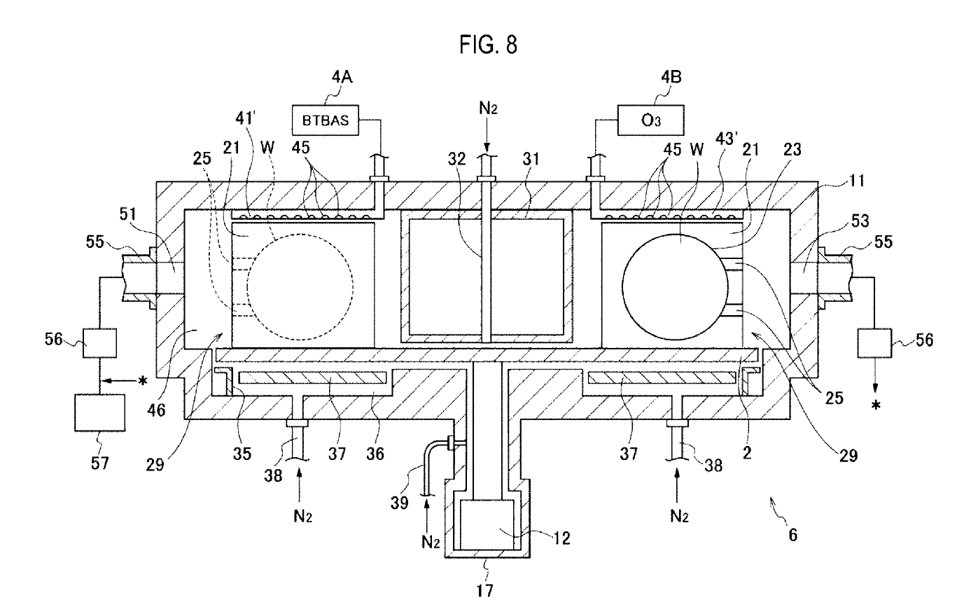

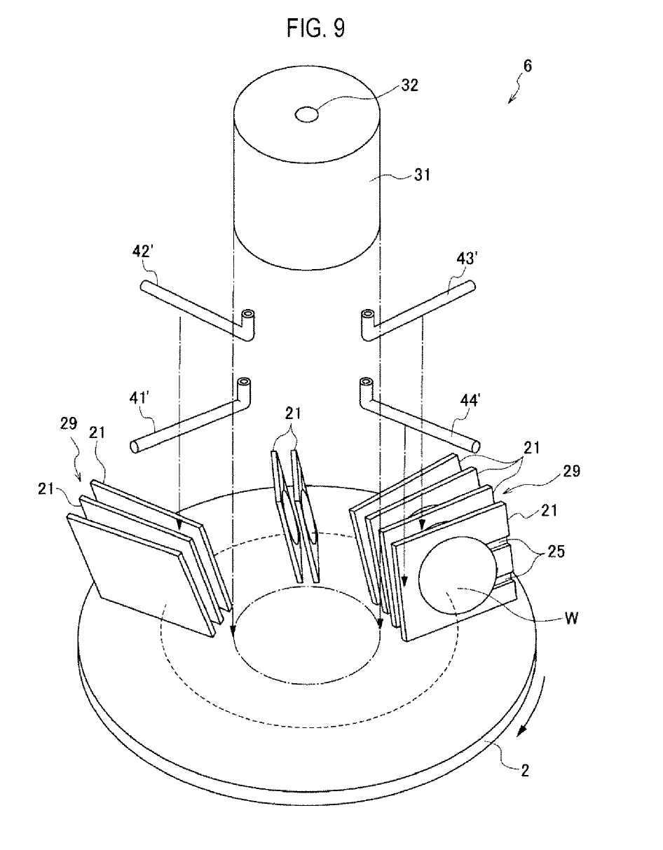

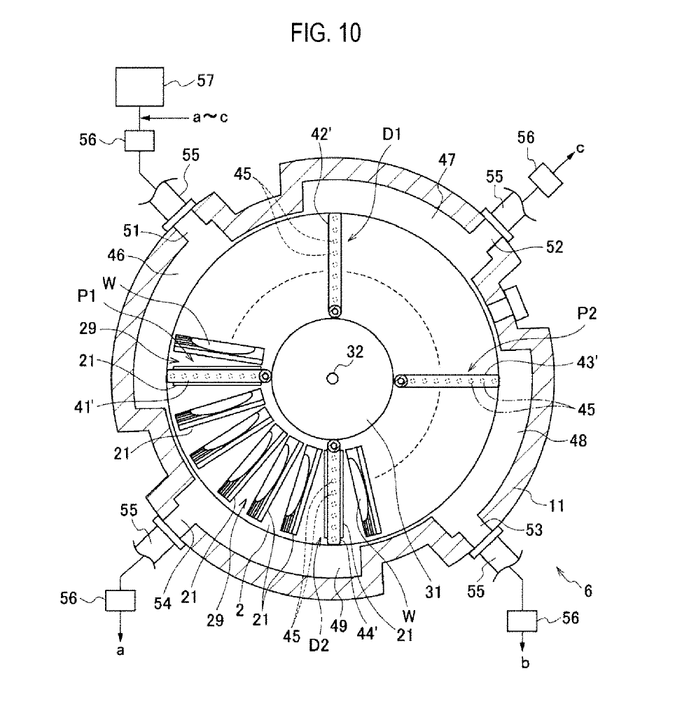

A film forming apparatus 6 according to a second embodiment will be described with a focus on the differences from the film forming apparatus 1 of the first embodiment. FIG. 8 is a longitudinal sectional view of the film forming apparatus 6, FIG. 9 is an internal exploded perspective view of the film forming apparatus 6, and FIG. 10 is a cross-sectional plan view of the film forming apparatus 6. Gas nozzles 41′ to 44′ of the film forming apparatus 6 are structured to extend from the outside of the vacuum vessel 11 into the vacuum vessel 11, like the first embodiment, but are different from the first embodiment in that the gas nozzles 41 to 44 of the film forming apparatus 6 are bent within the vacuum vessel 11 and horizontally extend above the wafer holding units 21 toward the peripheral portion of the rotatable table 2 along the radial direction of the rotatable table 2.

In the horizontally extended portions of the gas nozzles 41′ to 44′, a plurality of discharge holes 45 is formed to be opened at regular intervals along the longitudinal direction of the gas nozzles 41′ to 44′. The discharge holes 45 are opened downward such that a gas flow orienting downward from above each of the wafer holding units 21 is formed. Also in the second embodiment, the discharge holes 45 of the gas nozzles 41′ and 43′ are opened to face the processing zones P1 and P2, and the discharge holes 45 of the gas nozzles 42′ and 44′ are opened to face the separating zones D1 and D2. That is to say, the processing zones P1 and P2 and the separating zones D1 and D2 are formed below the gas nozzles 41′ to 44′.

The film forming apparatus 6 has the same configuration as the film forming apparatus 1 except that the configuration of the gas nozzles 41′ to 44′ is different as described above and the grooves 34 for accommodating the gas nozzles 41 to 44 of the film forming apparatus 1 are not formed in the side of the median separation part 31. The film forming process by the film forming apparatus 6 is performed with the same procedure as the film forming apparatus 1 to supply each gas into the vacuum vessel 11. In this film forming process, the processing gases and the separating gas discharged from the gas nozzles 41′ to 44′ flow downward toward the rotatable table 2 through the spaces 29A formed between the wafer holding units 21, followed by colliding with the rotatable table 2, followed by flowing to the peripheral portion of the rotatable table 2 by virtue of suction of the exhaust ports 51 to 54, thus being exhausted outside. Accordingly, each gas, after being supplied onto the rotatable table 2, is flown in the same way as the first embodiment, so that the same gas flow as the first embodiment when viewed from the top is formed inside the vacuum vessel 11. That is, while preventing a BTBAS gas not adsorbed on the wafer W from being introduced into the second processing zone P2, preventing an O₃ gas not adsorbed on the wafer W from being introduced into the first processing zone P1, and preventing the BTBAS gas and the O₃ gas from reacting with each other in the center of the rotatable table 2, the film forming process for the wafers W is progressed.

As described above, the BTBAS gas and the O₃ gas supplied from the gas nozzles 41′ and 43′ flow to the rotatable table 2 so that a laminar flow directing downward along the front surface of each of the wafers W is formed. The wafers W alternately pass through the processing zones P1 and P2 in which the laminar flow is formed so that a silicon oxide film is formed on each of the wafers W. According to the film forming apparatus 6, like the film forming apparatus 1 of the first embodiment, it is possible to prevent the gas flow from being disturbed due to collision of the processing gases with the front surface of each of the wafers W and increase the number of the wafers W to be loaded on the rotatable table 2. Accordingly, the film forming apparatus 6 of the second embodiment has the same advantages as the film forming apparatus 1 of the first embodiment.

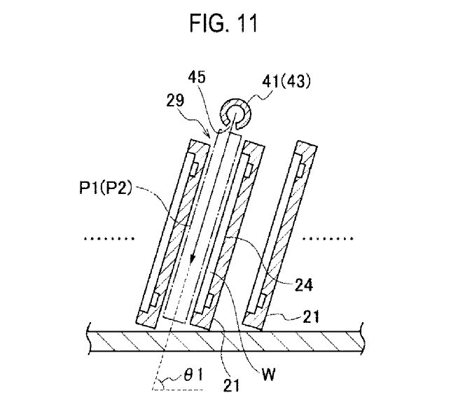

As described above, it is preferable in some embodiments to prevent collision of the processing gases in the plane of the wafer W. To do this, the discharge holes 45 of the processing gas nozzles 41′ and 43′ may be opened vertically downward. Alternatively, as shown in FIG. 11, the discharge holes 45 may be obliquely opened. As an example, it is effective to set an angle θ1 between the opening direction of the discharge holes 45 and the horizontal plane of the rotatable table 2 to be equal to the angle θ between the bottom 24 of the concave portion 23 of the wafer holding unit 21 (which is described with reference to FIG. 4) and the horizontal plane of the rotatable table 2.

### Third Embodiment

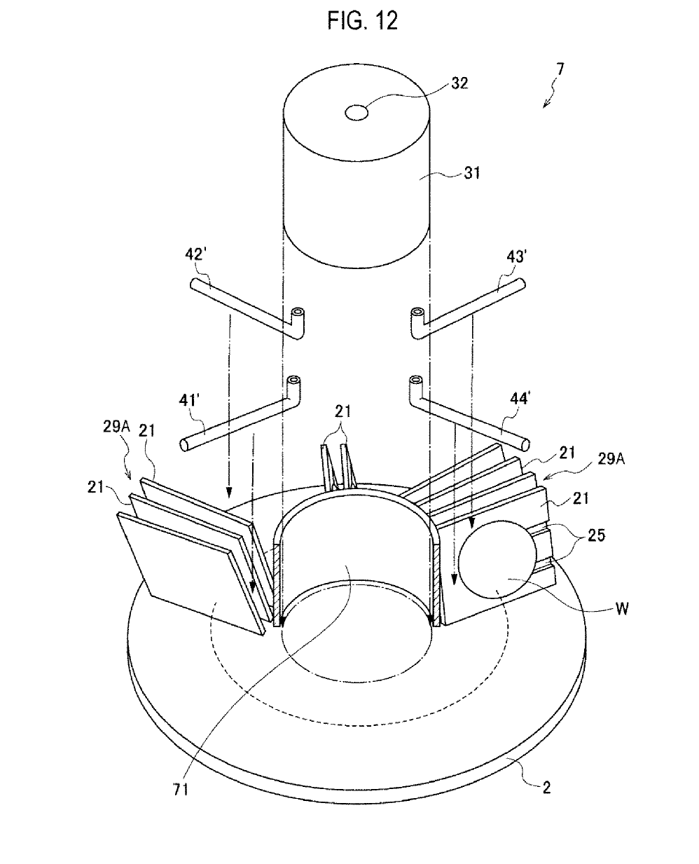

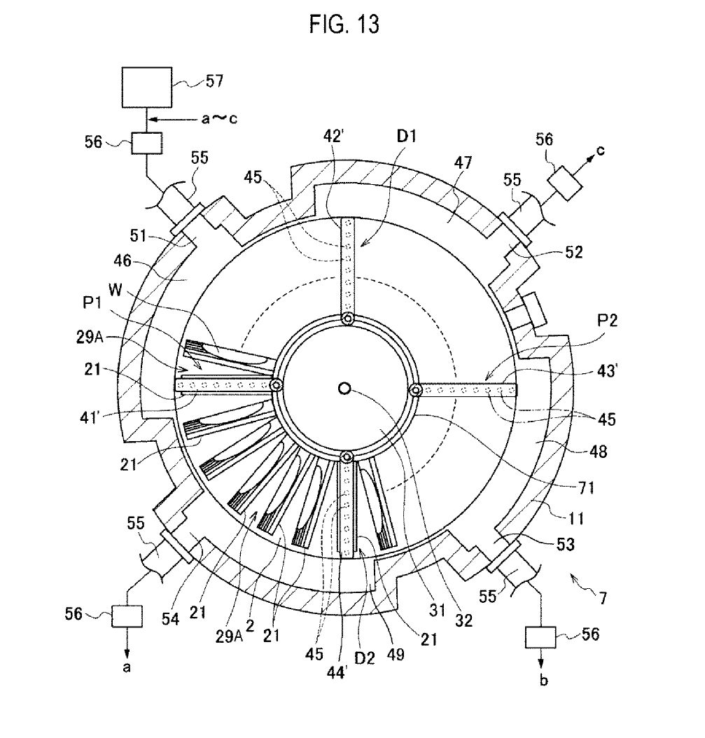

Next, a film forming apparatus 7 according to a third embodiment will be described with a focus on the differences from the film forming apparatus 6 of the second embodiment. FIG. 12 is an exploded perspective view of the interior of the film forming apparatus 7. FIG. 13 is a cross-sectional plan view of the film forming apparatus 7. The film forming apparatus 7 includes a cylindrical body 71 (used as a partition wall) installed upright on the rotatable table 2 so as to surround the median separation part 31. The cylindrical body 71 is rotated along with the rotatable table 2 while its lower end is in contact with the rotatable table 2 and its upper end is formed to be lower than the gas nozzles 41′ to 44′. The wafer holding units 21 are installed to extend from an outer circumferential surface of the cylindrical body 71 to the peripheral portion of the rotatable table 2. Thus, the spaces 29A between adjacent wafer holding units 21 are partitioned from each other by the cylindrical body 71. The configuration of the film forming apparatus 7 is similar to that of the film forming apparatus 6 except that the cylindrical body 71 is installed.

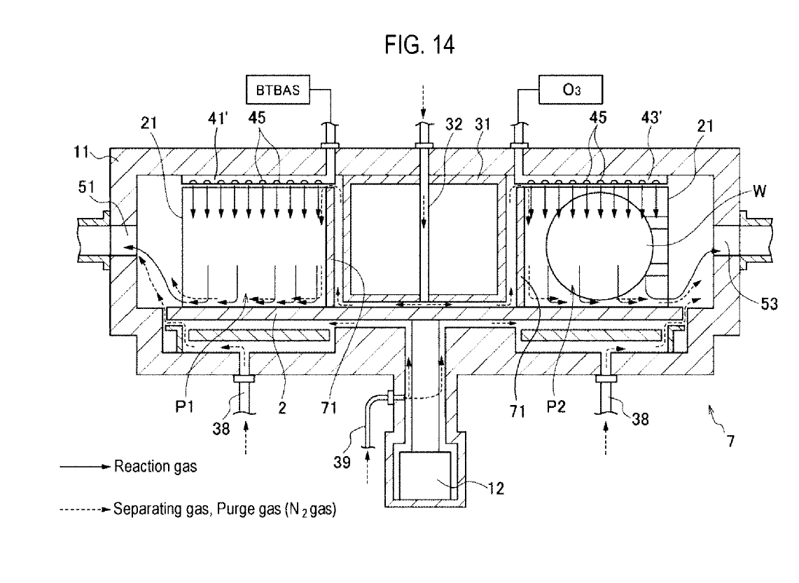

A film forming process by the film forming apparatus 7 is performed with the same procedure as the film forming apparatuses 1 and 6. FIG. 14 is a longitudinal sectional side view of the film forming apparatus 7. In FIG. 14, like FIG. 6, the flows of processing gases (reaction gas) in the film forming process are indicated by a solid arrow. The flow of a separating gas and a purge gas are indicated by a dotted arrow. A separating gas (N₂ gas) discharged from the central gas nozzle 32 of the median separation part 31 spreads radially below the median separation part 31, followed by flowing upward via a gap between an inner circumferential surface of the cylindrical body 71 and the outer circumferential surface of the median separation part 31, followed by flowing to the outside of the cylindrical body 71 through a gap between the upper end of the cylindrical body 71 and the ceiling plate of the vacuum vessel 11. Thereafter, as in the first and second embodiments, the separating gas is exhausted through the exhaust ports 51 to 54, along with gases discharged from the gas nozzles 41′ to 44′. As in the first and second embodiments, the separating gas is applied to prevent the BTBAS gas and the O₃ gas from contacting and reacting with each other above the center of the rotatable table 2.

The cylindrical body 71 and the separating gas supplied from the median separation part 31 prevents gases supplied from the gas nozzles 41′ to 44′ from flowing to the central portion of the rotatable table 2 so that the gases are exhausted through each of the exhaust ports 51 to 54. Therefore, according to the film forming apparatus 7 of the third embodiment, in addition to obtaining the same advantages as the film forming apparatuses 1 and 6 of the first and second embodiments, it is possible to reliably prevent reaction of the BTBAS gas with the O₃ gas above the central portion of the rotatable table 2. As a result, it is possible to more reliably prevent products produced by the reaction from being scattered as particles into the vacuum vessel 11.

### Fourth Embodiment

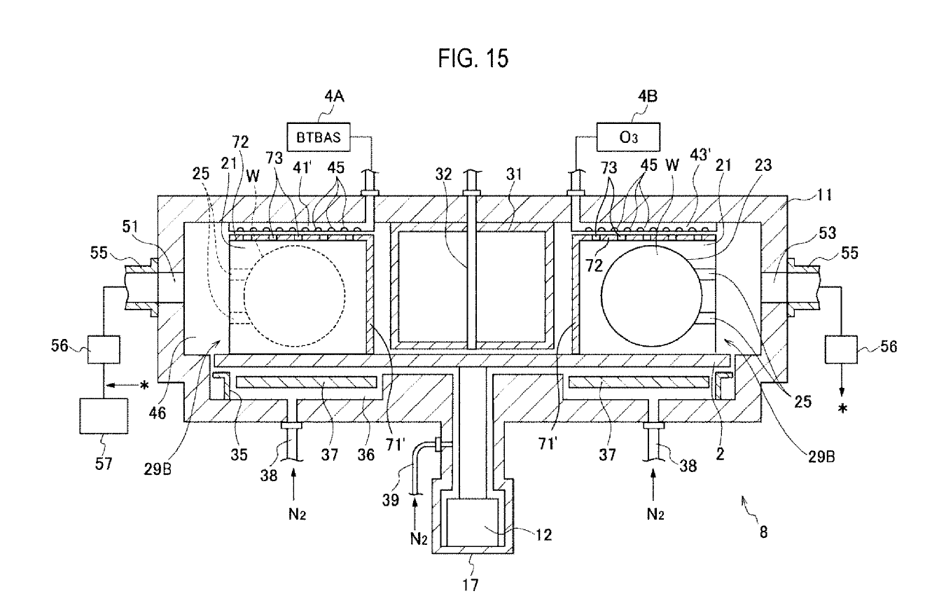

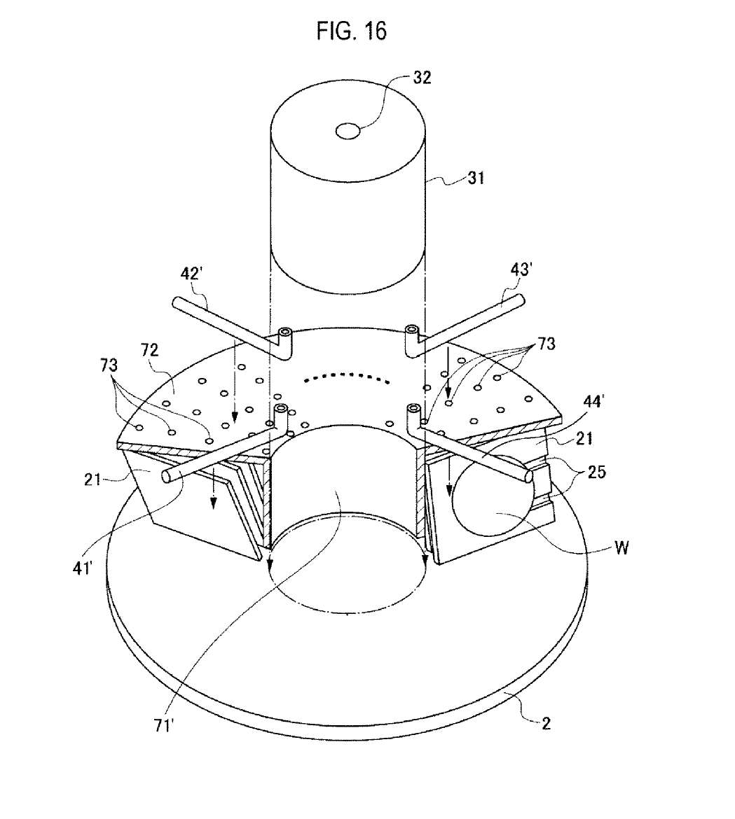

Next, a film forming apparatus 8 according to a fourth embodiment will be described with a focus on the differences from the film forming apparatus 7 of the third embodiment. FIG. 15 is a longitudinal sectional side view of the film forming apparatus 8. FIG. 16 is an exploded perspective view of the interior of the film forming apparatus 8. The film forming apparatus 8 includes a cylindrical body 71′, like the film forming apparatus 7. However, unlike the third embodiment, an upper end of the cylindrical body 71′ extends horizontally outward, forming a ring-like partition plate (or partition wall) 72 when viewed from the top. An upper end of each of the wafer holding units 21 is brought into contact with a lower surface of the partition plate 72. Thus, spaces 29B between the wafer holding units 21 are defined by spaces between adjacent wafer holding units 21 and the partition plate 72.

The partition plate 72 includes a plurality of gas inlets 73 opened to form rows along its radial direction. The rows of the gas inlets 73 are formed at intervals in the rotational direction of the rotatable table 2 so as to supply a gas into the respective spaces 29B. A configuration of the film forming apparatus 8 according to the fourth embodiment is similar to that of the film forming apparatus 7 according to the third embodiment except that the partition plate 72 is installed.

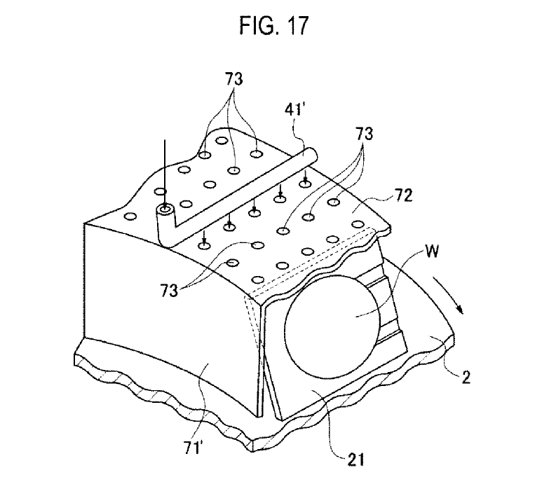

A film forming process by the film forming apparatus 8 is performed with the same procedure as the film forming apparatuses of the above embodiments. Each gas discharged from each of the gas nozzles 41′ to 44′ is introduced toward the front surface of each of the wafer holding units 21 through the gas inlets 73 located below each of the gas nozzles 41′ to 44′ such that a lamina flow flowing along the front surface of each of the wafers W is formed. Subsequently, the lamina flow flows toward the peripheral portion of the rotatable table 2 and is exhausted. Although it is representatively shown in FIG. 17 that the BTBAS gas is discharged from the first processing gas nozzle 41′ into the gas inlets 73, gases are supplied from the other gas nozzles 42′ to 44′ into the gas inlets 73 in the similar way. Even in the film forming apparatus 8, contact of the BTBAS gas and the O₃ gas in the central portion of the rotatable table 2 is more reliably prevented, thus obtaining the same advantages as the film forming apparatus 7.

In the first embodiment, the partition plate 72 may be formed. In this case, the gas inlets 73 may not be formed. By installing the partition plate 72 to block upper sides of each of the spaces 29B, a range where the BTBAS gas and the O₃ gas can be flown in the vacuum vessel 11 is more limited. This prevents the processing gases from being mixed above the rotatable table 2 more reliably.

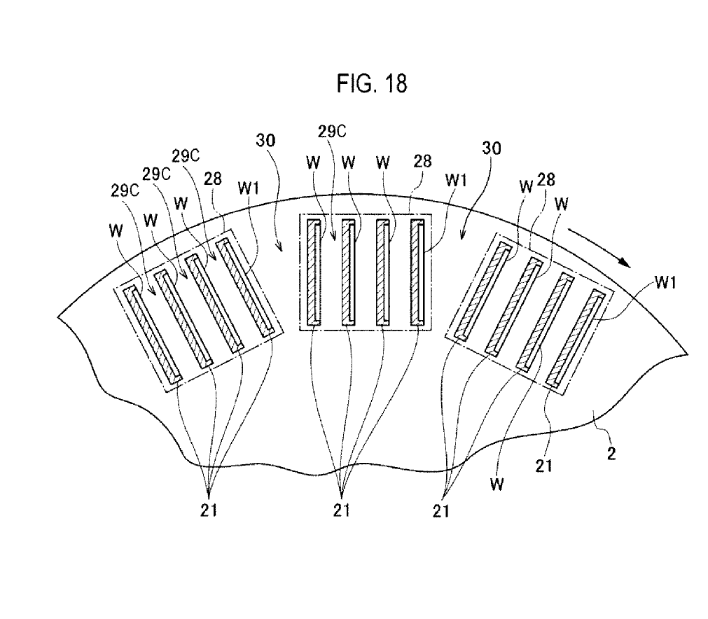

In the above embodiments, by arranging the wafer holding units 21 at regular intervals in the rotational direction of the rotatable table 2, deviations in flow rate and flow velocity of processing gas between the wafers W are suppressed, thus performing the film forming process for every wafer W with high uniformity. FIG. 18 shows another example of arrangement of the wafer holding units 21. In this arrangement example, a plurality of groups 28, each of which consists of four wafer holding units 21 arranged along the tangential direction of the rotatable table 2, is installed on the rotatable table 2 in the rotational direction of the rotatable table 2. The wafer holding units 21 in each of the groups 28 are located at regular intervals, and spaces 29C between adjacent wafer holding units 21 are formed in parallel to each other when viewed from the top. A space 30 between adjacent groups 28 is formed to be widened from the center of the rotatable table 2 toward the periphery thereof.

As described above, the shapes of the spaces 29C and 30 are different from each other. As such, in the same group 28, a flow rate and flow velocity of a supplied processing gas may be varied between the head wafer holding unit 21 and the subsequent three wafer holding units 3 in the rotation direction of the rotatable table 2. To cope with this situation, a dummy wafer W1 is held in the head wafer holding unit 21 and the other wafers W are held in the subsequent wafer holding units 21. In this configuration, the film forming process is performed. This allows the flow rate and flow velocity of the processing gas supplied to each of the wafers W to be uniform between the subsequent wafer holding units 21, which makes it possible to suppress a deviation in film thickness for every wafer W.

Even when the film forming process is performed with the dummy wafer W1 loaded in the wafer holding unit 21 in the manner as described above, a plurality of wafer holding units 21 can be installed on the rotatable table 2, thereby increasing throughput. In addition, in the arrangement example of the wafer holding units 21 shown in FIG. 18, the spaces 29C between the wafer holding units 21 in the same group 28 are formed to have equal intervals over the center and peripheral portion of the rotatable table 2 when viewed from the top. With this configuration, the processing gas can be supplied with higher uniformity over the center and peripheral portion of the rotatable table 2, thus enhancing a film thickness uniformity in the plane of the wafers W.

In addition, the exhaust ports 51 to 54 are not limited to being formed in the lateral surface of the vacuum vessel 11 but may be formed in, for example, the bottom of the vacuum vessel 11. As an example, the exhaust ports 51 to 54 may be formed in positions beyond the peripheral portion of the rotatable table 2. This formation prevents a gas flown to the peripheral portion of the rotatable table 2 from being returned to the central portion of the rotatable table 2, thereby preventing a flow of the gas on the surface of the wafer W from being disturbed.

A film formed by performing the ALD process in the aforementioned film forming apparatus is not limited to the silicon oxide film but may be, for example, a silicon nitride film, an aluminum nitride film or the like. In addition, while in the above embodiments, the film forming apparatus has been described to perform the ALD process by alternately supplying two types of the processing gases, the present disclosure is not limited thereto. In some embodiments, the film forming apparatus may perform a CVD (Chemical Vapor Deposition) process by supplying only one type of processing gas to the wafers W. Furthermore, the present disclosure is not limited to the aforementioned film forming apparatuses. In some embodiments, the present disclosure may be applied to a modification apparatus which includes a plasma forming unit configured to supply a processing gas to the rotatable table 2 and form plasma thereabove. The modification apparatus modifies a film formed on a front surface of the wafer W using the plasma. In some embodiments, the present disclosure may be applied to an annealing apparatus which heats a substrate while supplying a gas onto the substrate. As an example, when the CVD apparatus and the annealing apparatus is applied, no separating gas nozzle may be installed.

According to the present disclosure in some embodiments, a plurality of substrates is held by a plurality of substrate holding units which is circumferentially arranged on a rotatable table in a state where the substrates are obliquely loaded into the respective substrate holding units. Further, the substrates are held by the substrate holding units with a front surface of each of the substrates oriented in a direction that the rotatable table rotates. This allows more substrates to be arranged on the rotatable table than horizontally holding the substrates on the rotatable table. Accordingly, the number of substrates which can be processed at once can be increased, thereby increasing throughput. In addition, by holding the substrates in this manner, a processing gas can flow over the front surfaces of the substrates, which makes it possible to prevent the processing gas from colliding with and staying on the front surfaces of the substrates. As a result, it is possible to prevent a distribution of processing gas in the plane of the substrate from being disturbed, thereby increasing an in-plane uniformity of the substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A vacuum processing apparatus, comprising:
a rotatable table installed in a vacuum vessel and configured to horizontally rotate around its center axis;
a drive mechanism configured to rotate the rotatable table;
a plurality of substrate holding units circumferentially arranged on the rotatable table and configured to obliquely hold a plurality of substrates with a front surface of each of the substrates oriented in a rotation direction of the rotatable table;
a heating unit configured to heat the substrates held by the substrate holding units;
a processing gas supply unit configured to supply a processing gas onto the substrates held by the substrate holding units; and
a vacuum exhaust mechanism configured to vacuum-exhaust the interior of the vacuum vessel.

2. The vacuum processing apparatus of claim 1, wherein the processing gas supply unit is disposed between a central portion of the rotatable table and an area where the substrate holding units are arranged and is configured to supply the processing gas toward the area.

3. The vacuum processing apparatus of claim 1, wherein the processing gas supply unit is disposed in an upper side of an area where the substrate holding units are arranged and is configured to supply the processing gas toward the area.

4. The vacuum processing apparatus of claim 3, wherein a first partition wall is installed to partition the area where the substrate holding units are arranged and a central portion of the rotatable table.

5. The vacuum processing apparatus of claim 3, wherein a second partition wall is installed to partition the area where the substrate holding units are arranged and a ceiling plate of the vacuum vessel, and
wherein the second partition wall includes a plurality of gas inlets through which the processing gas supplied from the processing gas supply unit is introduced into respective spaces formed between the plurality of substrate holding units.

6. The vacuum processing apparatus of claim 1, wherein the vacuum vessel includes exhaust ports through which the inside of the vacuum vessel is exhausted, the exhaust ports being formed at positions beyond a peripheral portion of the rotatable table in the vacuum vessel.

7. The vacuum processing apparatus of claim 1, wherein the processing gas supply unit includes:
a raw material gas supply unit configured to supply and adsorb a raw material gas onto the substrate; and
a reaction gas supply unit spaced apart from the raw material gas supply unit in the rotation direction of the rotatable table and configured to supply a reaction gas onto the substrate, the reaction gas reacting with the raw material gas adsorbed on the substrate to generate a reaction product.

8. The vacuum processing apparatus of claim 7, further comprising: a separating gas supply unit installed between the raw material gas supply unit and the reaction gas supply unit in a circumferential direction of the rotatable table, and configured to supply a separating gas to separate the raw material gas from the reaction gas.

9. The vacuum processing apparatus of claim 7, wherein a first exhaust port through which the raw material gas is exhausted and a second exhaust port through which the reaction gas is exhausted are formed to be distanced from each other in a circumferential direction of the vacuum vessel.

10. The vacuum processing apparatus of claim 1, wherein the substrate holding units are arranged in such a manner that a space between adjacent substrates is widened from an inner side toward an outer side when viewed from the top.

11. The vacuum processing apparatus of claim 1, wherein the plurality of substrate holding units is divided into a predetermined number of groups which are disposed along the circumferential direction of the rotatable table,
wherein the plurality of substrate holding units in each of the groups hold the respective substrates such that they are arranged in parallel to each other when viewed from the top.
